(19) United States
(12) Patent Application Publication
(10) Pub. No.: US 2011/0314901 A1
(43) Pub. Date: Dec. 29, 2011

(54) PHOTOELECTRIC GAS SENSOR DEVICE AND MANUFACTURING METHOD THEREOF

(75) Inventor: TZONG-SHENG LEE, (US)

(73) Assignees: SHENZHEN SCP TECHNOLOGY LTD; UniMEMS Manufacturing Co., Ltd.

(21) Appl. No.: 12/897,002

(22) Filed: Oct. 4, 2010

(30) Foreign Application Priority Data
Jun. 28, 2010 (TW) 99121023

(51) Int. Cl. G01N 21/17; H05K 13/00

(52) U.S. Cl. 73/24.02; 29/592.1

(57) ABSTRACT

The instant disclosure provides a photoelectric gas sensor device and a manufacturing method thereof. The manufacturing method comprising the steps of: (A) providing at least two half-housing modules from at least one corresponding mold; (B) forming a reflecting layer on the ellipsoidal inner surface of the chamber unit; (C) forming a chamber unit having a reflective ellipsoidal inner surface defining a chamber space from the half-housing modules; (D) forming a reflecting layer on each inner surface of the two half-housings; and (E) disposing an emitter assembly having an energy emitter at the first focal point of the ellipsoidal chamber. A fine-adjustment mechanism may be further provided to enable clearance adjustment between the half-housing modules.

### BACKGROUND OF THE INVENTION

1. Field of the Invention

The present invention relates to a gas sensor device and a manufacturing method thereof, and particularly to a photoelectric gas sensor device and a manufacturing method thereof.

2. Description of Related Art

Many types of gas sensors are developed to detect toxic, flammable, explosive, or asphyxiant gases harmful to human body. Common types of gas sensors include electrochemical gas sensors, solid electrolyte gas sensors, semiconductor gas sensors, and optical gas sensors. While the underlying principles behind different types of detectors may be different, the development emphasis and performance requirements, such as high sensitivity, low manufacturing cost, good selectivity, quick reaction, high stability and repeatability, remain the same.

The electrochemical gas sensor detects a gas by dissolving the gas in a liquid electrolyte to trigger an oxidation-reduction reaction and measuring the variation in electric potential and current resulting from the reaction.

The solid electrolyte gas sensor employs a cathode material, an anode material, and a solid ionic conductive electrolyte. The concentration difference between the gases at the cathode and the anode creates an electric potential difference. If the gas concentration at one pole is known, the concentration of the gas at the other pole can be obtained by using Nernst equation.

Semiconductor gas sensor utilizes detectors made by metallic-oxide materials. The metallic-oxide in the detector absorbs gas molecules and causes a resistance variation. The semiconductor gas sensor measures the resultant resistance variation to monitor the gas concentration variations in the surrounding environment.

The optical gas sensor detects a gas by an infrared absorption method. FIG. 1 shows a design of a conventional optical sensor. The optical sensor module includes a chamber 1a, an infrared light source 2a, a spectral filter 3a, and an optical sensor 4a. Chamber 1a has two convection passages 11a to permit gas flow in and out of the chamber. The infrared light source 2a emits an infrared light having a specific range of wavelength. The infrared light is reflected in the chamber 1a to the spectral filter 3a. The spectral filter 3a only permits infrared light having a specific range of wavelength to the optical sensor 4a. When a harmful gas is present, the gas molecules may absorb or deflect the infrared light emitted from the light source. The energy level of the infrared beam received at optical sensor 4a is therefore reduced. Thus, the optical gas sensor measures the variation of light intensity to distinguish and measure the type and the concentration of a gas. However, the average incidental angle of the incoming energy beams to the conventional optical sensor is too large, resulting in weak signal reception in the conventional optical sensors.

Therefore, the invention provides a gas sensor module and device to mitigate and/or obviate the aforementioned problems.

### SUMMARY OF THE INVENTION

An object of the instant disclosure is to provide a photoelectric gas sensor device and a manufacturing method thereof. Particularly, the instant disclosure provides an easier and more cost-effective method of producing a photoelectric gas sensor device that has improved selectivity and signal reception strength. Furthermore, the receiver assembly of the instant photoelectric gas sensor may be fine-tuned to uniformly receive energy from the emitter assembly.

The manufacturing method of the photoelectric gas sensor device comprising the steps of: (A) providing at least two half-housing modules from at least one corresponding forming mold; (B) forming a reflecting layer on the inner surface of each half-housing module; (C) forming a chamber unit having an reflective ellipsoidal inner surface defining an ellipsoidal inner chamber space from the at least two half-housing modules; (D) disposing an emitter assembly having an energy emitter at the first focal point of the ellipsoidal chamber; and providing a receiver assembly disposed on a second focal point of the ellipsoidal chamber.

Another aspect of the instant disclosure is to provide a photoelectric gas sensor device comprising: (A) a chamber unit having an ellipsoidal inner surface defining a chamber and two identical half-housings, the chamber unit includes at least one convection passage permitting gas communication to the inner chamber, and the chamber unit may be formed by two identical half-housing modules; (B) a reflecting layer disposed on the inner surface of the chamber unit; (C) a fine-adjustment mechanism for enabling clearance-adjustment between the half-housing modules; (D) an emitter assembly having an energy emitter located on a first focal point of the ellipsoidal chamber; and (E) a receiver assembly having a detector unit located on a second focal point of the ellipsoidal chamber;

The instant disclosure utilizes the geometric property of an ellipsoid to improve the selectivity and signal reception strength of the gas sensor. Also, because the chamber unit may be formed by identical half-housing modules, the production cost and manufacturing process can be significantly lowered and simplified. Furthermore, the fine-adjustment mechanism of the instant photoelectric gas detector may provide additional optimization for the receiver assembly to uniformly receive energy beams from the emitter assembly, thereby further improving the selectivity and signal reception quality of the gas sensor.

For further understanding of the present invention, reference is made to the following detailed description illustrating the embodiments and examples of the present invention. The description is for illustrative purpose only and is not intended to limit the scope of the claim.

### BRIEF DESCRIPTION OF THE DRAWINGS

FIG. 1 is a schematic view of the prior art;

FIG. 2 is a step flow chart of the present invention;

FIG. 3 is a three-dimensional view of the half-housing of the present invention;

FIG. 4 is a three-dimensional view of the present invention as the first fine-adjustment mechanism is screws;

FIG. 5 is a three-dimensional view of the present invention as the first fine-adjustment mechanism is gaskets;

FIG. 6 is a three-dimensional view of the present invention as the second fine-adjustment mechanism is screws;

FIG. 7 is a diffusion state view of the present invention;

FIG. 8 is a schematic view of the present invention;

FIG. 9 is a schematic view of the present invention as the two half-housings are spaced disposed;

FIG. 10 is a three-dimensional view of the present invention.

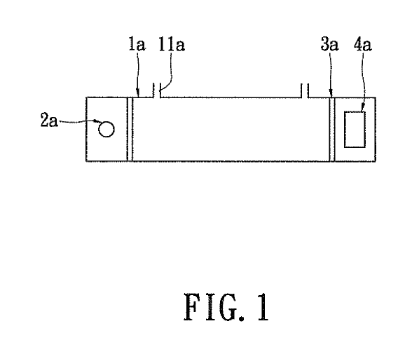

### DETAILED DESCRIPTION OF THE PREFERRED EMBODIMENTS

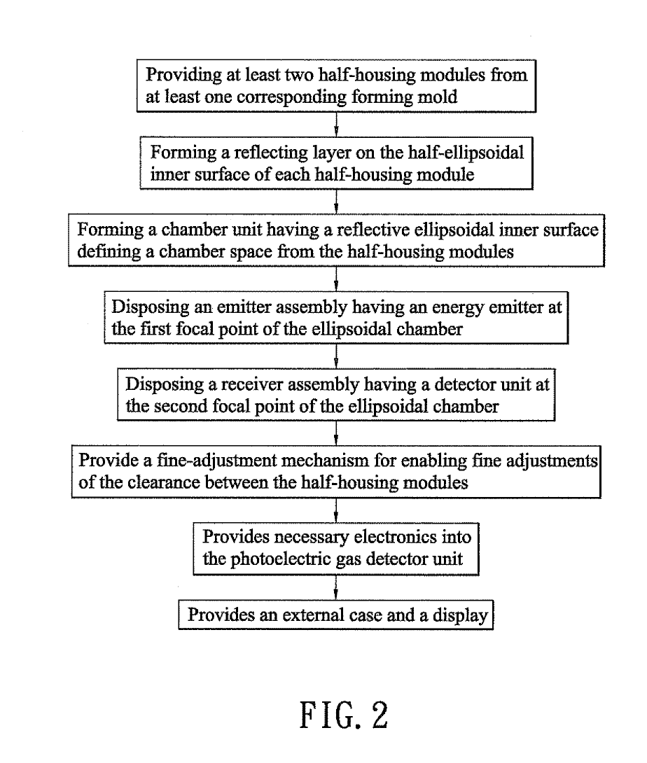

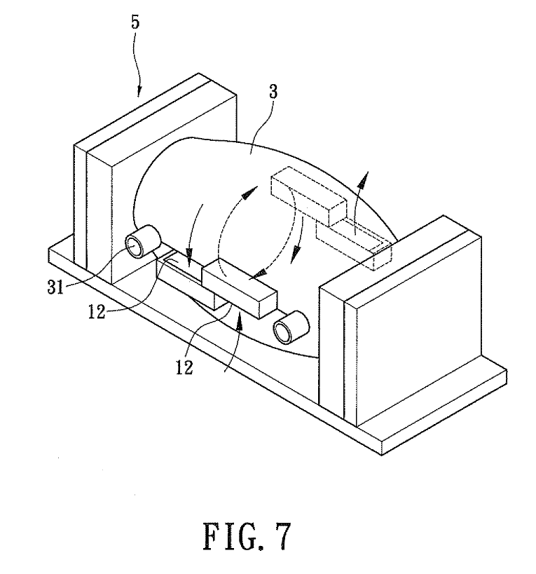

To achieve the objective of providing a photoelectric gas sensor device according to the instant disclosure (such as illustrated in FIG. 7-9), a flow chart comprising detailed manufacturing steps is provided in FIG. 2.

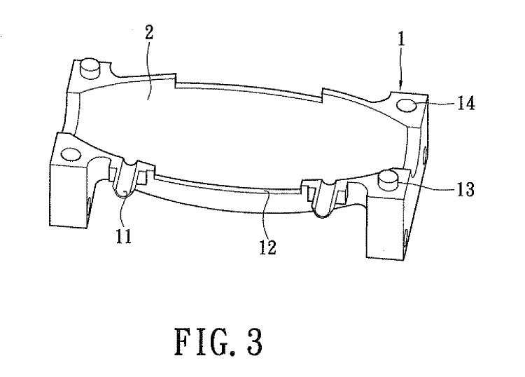

Referring to FIG. 2, the manufacturing method comprises the following steps. (1) Providing at least two half-housing modules 1 from at least one corresponding forming mold (as shown in FIG. 3). Each half-housing module may include at least one half-convection-opening 11 or a half-diffusion-opening 12; at least one protruding joint 13; at least one recessing slot 14; and a substantially half-ellipsoidal inner surface formed thereon. In the instant embodiment, half-housing module 1 comprises a pair of half-diffusion-openings 12, a pair of half-convection-openings 11, a pair of protruding joint 13 and recessing slot 14. However, the number of these elements may be configured differently to fit specific operational requirements. The half-housing module 1 may be formed by an injection molding method or a perfusion forming method.

(2) Forming a reflecting layer 2 on the half-ellipsoidal inner surface of each half-housing module 1. The reflecting layer 2 may be disposed on the inner surface of the half-housing module 1 by a variety of conventional methods. For example, for a plastic half-housing module made by an injection method, the reflective layer may be disposed on the inner surface by a film coating applicator; for a half-housing module made by metal materials, an internal surface polishing method or an electroplating method may be effectively used to obtain the reflecting effect on the inner surface.

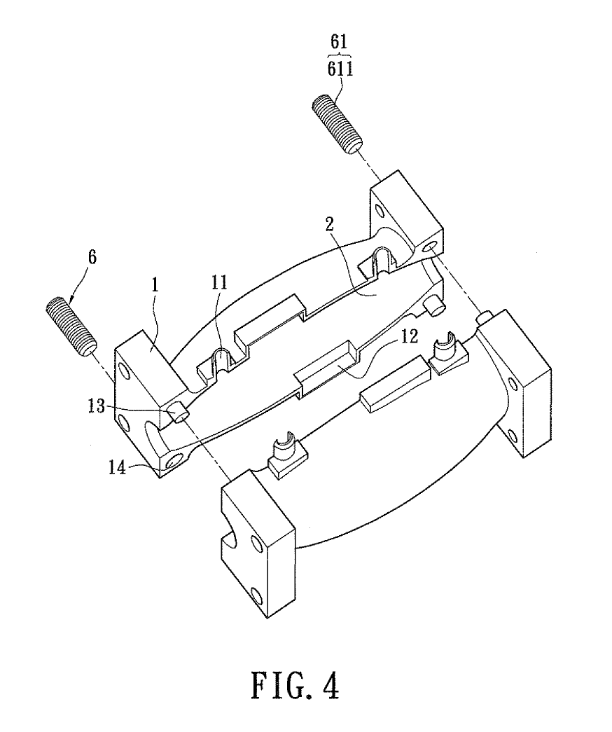

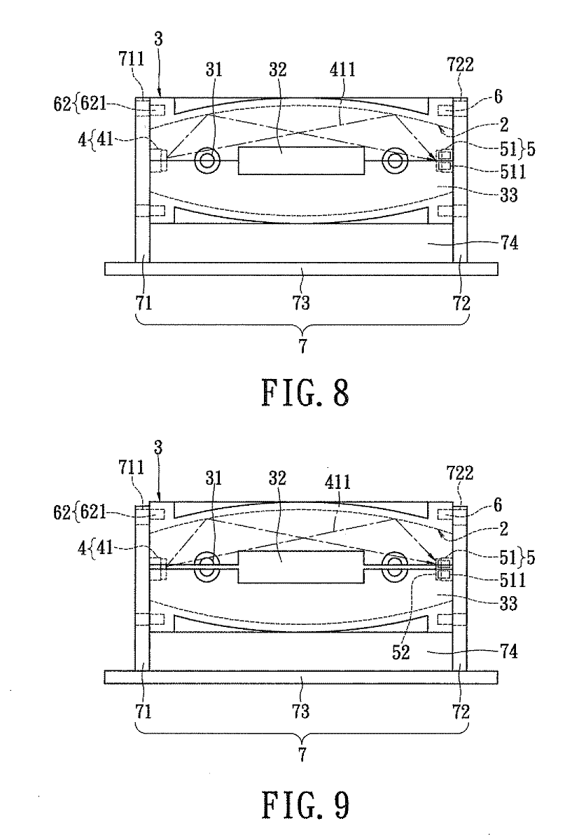

(3) Forming a chamber unit 3 having a reflective ellipsoidal inner surface defining a chamber space from the half-housing modules (as shown in FIG. 4). By joining the half-ellipsoidal modules, the reflective half-ellipsoidal inner surface of the half-housing modules are combined to jointly define a substantially ellipsoidal inner chamber space 33 (shown in FIGS. 8 and 9). Particularly, in the instant embodiment, the half-convection-openings 11 and the half-diffusion-openings 12 of the half-ellipsoid modules are matchingly arranged to form a pair of convection passages 31 and diffusion passages 32 on the chamber unit 3. For one thing, the convection holes 31 and the diffusion holes 32 are formed on the coupling interface of the two half-housing modules 11. Thus, gas molecules can flow into the inner chamber space 33 via the convection holes 31 and/or the diffusion holes 32. Moreover, the half-diffusion-openings of the half-housing modules 1 can be arranged in a staggered configuration as illustrated in FIG. 7.

The remaining manufacturing steps include: (4) Disposing an emitter assembly having an energy emitter at the first focal point of the ellipsoidal chamber and (5) disposing a receiver assembly having a detector unit at the second focal point of the ellipsoidal chamber.

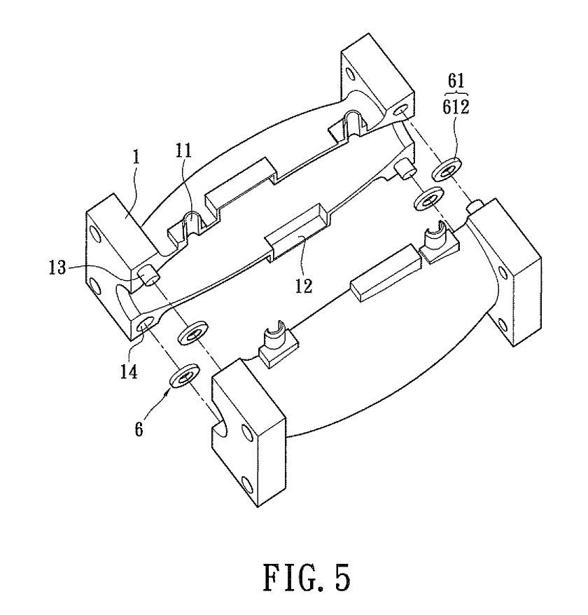

Furthermore, a step (6) may be included to provide a fine-adjustment mechanism 6 for enabling fine adjustments of the clearance between the half-housing modules. By finely adjusting the clearance between the two half-housings 1, the energy beam reflected to the receiver assembly 5 may be tuned to form an optimized focusing plane 52. For example, the reflected energy beam may be adjusted to form an elliptic or a dumbbell shaped focusing plane on the detector unit of the receiver assembly 5, thus increasing the signal reception and selectivity of the photoelectric gas sensor. The fine-adjustment mechanism 6 has a first fine-adjustment mechanism 61 (as FIG. 4 and FIG. 5 shown). The two half-housings 1 are spaced disposed by moving the first fine-adjustment mechanism 61 to make the focusing plane 52 forming an ellipsoidal shape or a dumbbell shape.

Next, step (7) provides necessary electronics into the photoelectric gas detector unit. Particularly, the step includes providing a circuit board assembly 7 having a first circuit board 71, a second circuit board 72, and a third circuit board 73.

The first circuit board 71 is electrically connected to the emitter assembly 4. And, connecting the first circuit board 71 to a first edge of the housing 3.

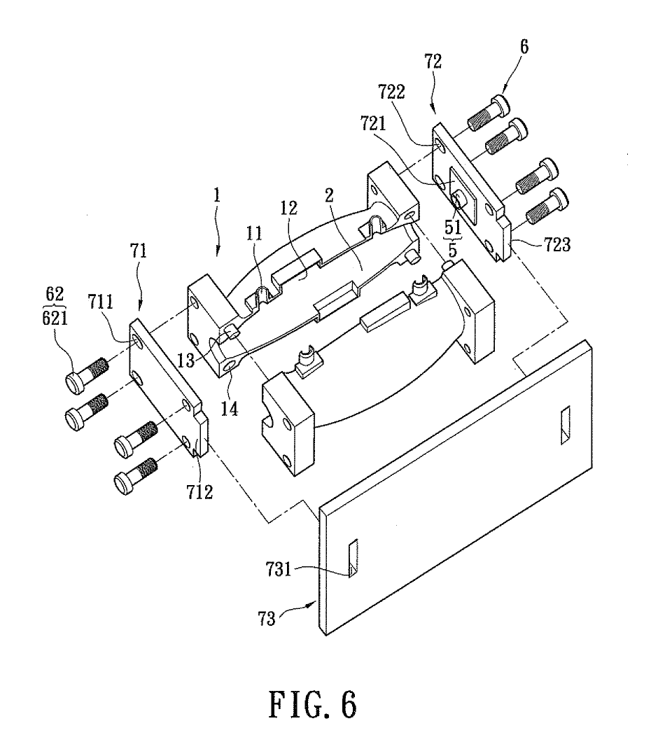

The second circuit board 72 is electrically connected to the receiver assembly 5. And, forming an amplifier 721 (as FIG. 6 shown) on the second circuit board 72. Connecting the second circuit board 72 to a second edge of the housing 3, the second edge opposing to the first edge, wherein the first edge and the second edge are perpendicular to a major axis of the ellipsoidal chamber 33.

The third circuit board 73 is disposed under the housing 3, and two sides of the third circuit board 73 are respectively connected to the first circuit board 71 and the second circuit board 72.

The fine-adjustment mechanism 6 further has a second fine-adjustment mechanism 62 (as FIG. 6 and FIG. 9 shown). The second fine-adjustment mechanism 62 is disposed between the first circuit board 71 and the first edge of the housing 3, and between the second circuit board 72 and the second edge of the housing 3, thereby the two half-housings 1 are spaced disposed by moving the second fine-adjustment mechanism 62 to make the focusing plane 52 fowling an ellipsoidal shape or a dumbbell shape.

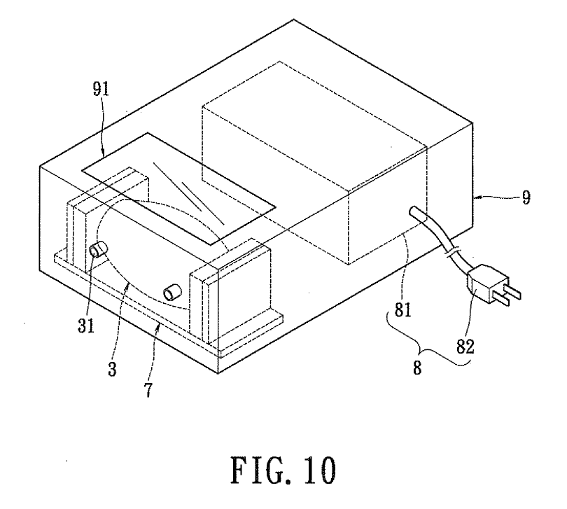

Finally, step (8) provides an external case 9 and a display 91 (as FIG. 10 shown). The display 91 is disposed above the housing 3 and fixed on the external case 9, and the display 91 is electrically connected to the third circuit board 73.

It should be noted that, although the instantly disclosed manufacturing steps are introduce in the above mentioned order, in practice, the steps need not be carried out in the exact order.

Another aspect of the instant disclosure is to provide a photoelectric gas sensor device made by the abovementioned steps. As FIG. 3 and FIG. 4 illustrate, the chamber unit 3 may comprise two identical half-housing modules 1. Each half-housing module 1 has two protruding joints 13 and two recessing slots 14. The protruding joints 13 are protruded on an interface of the half-housing 1, and the two recessing slots 13 are concaved corresponding to the two joints 13. The two half-housings 1 are connected by engaging joints 13 and the slots 14 to form housing 3. Therefore, the manufacturing of the instant photoelectric gas detector only requires a single mould structure to provide the half-housing modules. This design feature enables easy module forming, which would translate to convenient fabrication and lower production cost.

Furthermore, the chamber unit 3 has a substantially ellipsoidal inner surface that defines a substantially ellipsoidal inner chamber 33. A reflecting layer 2 is disposed on the ellipsoidal inner surface of the chamber unit 3. At least one convection passage is formed on the housing 3, permitting pas communication to the chamber 33. Additional diffusion passage 32 may be disposed on the chamber unit 3 to further enhance gas permittivity to the inner chamber 33. Moreover, the convection passage and the diffusion passage are formed on the interface of the two half-housing modules 1. Therefore, gas molecules may flow into the inner chamber 33 of the chamber unit 3 via the convection passage 31 and the diffusion passage 32.

The convection passage 31 and the diffusion passage 32 can be used in combination or separately to increase the sensor's adaptability to the surrounding environment. For instance, the diffusion passage 32 may be shut or sealed to permit gas-flow through only the convection passage 31 and vice versa.

Moreover, the chamber unit 3 may have only the convection passage 31 or only the diffusion passage 32, depending on the operation requirements. Furthermore, the diffusion passage may be of a staggered configuration as shown in FIG. 7. The staggered arrangement of the convection passage may help reducing gas disturbance from direct circulation in the inner chamber 33 or preventing scattered external heat energy from entering the inner chamber.

FIG. 8 shows the arrangement of the emitter assembly 4 and the receiver assembly 5. The emitter assembly 4 has an energy emitter located on the first focal point of the ellipsoidal chamber 33, and the receiver assembly 5 has a detector unit located on the second focal point of the ellipsoidal chamber 33. The inner surface of the chamber unit 3 is coated with a reflective layer 2. Utilizing the geometric property of an ellipsoid, the light emitted by the light source on the first focal point is reflected to the detector unit on the other focal point. The emitter assembly 4 comprises an infrared light emitter 41 capable of emitting infrared light beams 411, and the receiver assembly 5 has at least two non-dispersive optical sensors 51. Each non-dispersive optical sensor 51 has at least two detecting elements 511 for detecting a specific range of wavelength. Each detecting element 511 has a sensor chip (not shown) and a spectral filter (not shown) disposed correspondingly on the sensor chip. In operation, one of the detecting elements 511 serves as a reference while the other is used to detect the light intensity variation of the infrared light 411 at the receiver detector. Thus, the gas type and gas concentration may be determined by measuring the intensity variation of the infrared light beam 411. Moreover, having additional detecting elements 511 enables the sensor to detect more than one type of gas. For one thing, two sets of detecting elements 511 enables the sensor to detect one type of gas (one element is used as reference, while the second element detects one type of gas); three sets of detecting elements 511 enables the sensor to detect two types of gas; while a sensor having four sets of detecting elements 511 can detect up to three types of gas, etc.

Attention is now drawn to the fine-adjustment mechanism 6. There are many approaches to implement the fine-adjustment device for providing clearance adjustment between the half-housing modules. For example, as shown in FIG. 4, the first fine-adjustment mechanism 61 may be set-screws 611. The screws 611 movable screw in one of the half-housings 1, and one end of each screw 611 are contacted to the interface of the two half-housings 1. Space between the two half-housings 1 can be adjusted by spinning the screws 611. After the infrared light 411 reflected to the non-dispersive optical sensor 51, the infrared light 411 is formed the focusing plane 52 on the non-dispersive optical sensor 5, wherein the focusing plane 52 is an ellipsoidal shape or a dumbbell shape. Therefore, each detecting element 511 may receive a uniformly distributed infrared light signal 411, thereby increasing the signal reception strength and selectivity of the gas sensor unit.

Referring again to FIG. 5. As another exemplary embodiment, the fine-adjustment mechanism 61 may be spacers 612. The gaskets 612 are disposed between the two half-housings 1, and the focusing plane 52 can be formed an ellipsoidal shape or a dumbbell shape by using different thickness of the gaskets 612, thereby each detecting element 511 be uniform received the infrared light 411.

As shown in FIG. 6, the first circuit board 71 and the second circuit board 72 are electrically connected to the emitter assembly 4 and the receiver assembly 5 respectively. The first circuit board 71 has at least one adjustment hole 711 and an inserting edge 712 formed thereof, and the second circuit board 72 has at least one adjustment hole 721 and an inserting edge 722 formed thereof, wherein the adjustment holes 711,712 are elongated. The third circuit board 73 has two inserting holes 731 corresponding to the inserting edge 712,722. The inserting edge 712 of the first circuit board 71 and the inserting edge 722 of the second circuit board 72 are inserted into the adjustment holes 711,712 of the third circuit board 73. Because of the amplifier 721 on the second circuit board 72, noise of the signal transmission can be reduced effectively.

As shown in FIG. 6 and FIG. 9, the second fine-adjustment mechanism 62 is screws 621. The screws 621 pass through the adjustment holes 711 of the first circuit board 71 and the adjustment hole 722 of the second circuit board 72, wherein the screws 621 can slightly move in the adjustment holes 711,722 (as FIG. 9 shown), and then the screws 621 can fix the first circuit board 71 and the second circuit board 72 on the half-housings 1. By slightly adjusting space between the two half-housings 1, the focusing plane 52 can be formed an ellipsoidal shape or a dumbbell shape, thereby each detecting element 511 can be uniform received the infrared light 411. Moreover, the second fine-adjustment mechanism 62 is not only using alone, but also using with the first fine-adjustment mechanism 61. Besides, shape of the adjustment hole 621 in this disclosure is elongated, but it isn't a limit.

This disclosure has a simply install process, as FIG. 6 shown, screwing the first circuit board 71 and the second circuit board 72 to the two edges of the housing 3. Inserting the first circuit board 71 and the second circuit board 72 to the third circuit board 73, and then welding the first circuit board 71 and the second circuit board 72 to the third circuit board 73. Finally, gluing the welding place of the circuit board assembly 7. Cost can be reduced by the simply install process.

As shown in FIG. 8 and FIG. 9, the gas sensor device has a storage space 74 formed between the housing 3 and the circuit board assembly 7. The storage space 74 can be used to receive sensor components (not shown).

The gas sensor device can transmit an alert signal to a user via the circuit board assembly 7. The gas sensor device can also be used with an air condition system to detect the presence of harmful gases in the environment.

The instant disclosure has a power assembly 8 which is electrically connected to the circuit board assembly 7. The power assembly 8 comprises a battery 81 and a power plug 82. The battery 81 provides power to the gas sensor device when no external power supply is available; while the power plug 82 can be inserted into a socket (not shown) to provide power to the sensor device externally. The external case 9 is designed to enclose housing 3, emitter assembly 4, receiver assembly 5, circuit board assembly 7, and power assembly 8. The display 9 electrically connected to the circuit board assembly 7, thereby the display 9 can present the instant gas concentration which detecting by the gas sensor device.

The instant disclosure has several features, includes as follows. (1) The emitter assembly 4 and the receiver assembly 5 are respectively arranged on the two focal points of the ellipsoidal inner surface, and the emitter assembly 4 generates energy reflected to the receiver assembly 5 via the reflecting layer 2, whereby selectivity and signal reception strength of the gas sensor module can be improved. (2) The two half-housings 1 are the same, and the housing 3 is formed by the two half-housings 1 connected with each other, whereby when designing mould, it only needs one mould structure so as to provide easily forming and de-molding, convenient fabrication, and low cost. (3) The housing 3 has the convection passage and the diffusion passage, whereby the gas sensor module can be used with convection way or diffusion way according to user consideration. (4) The diffusion passage may be formed in staggered type, whereby it can prevent the gas overly disturb in the housing 3, and prevent external scattered heat enter to the housing 3. (5) By slightly adjusting the fine-adjustment mechanism 6 to control space between the two half-housings 1, the focusing plane 52 is the ellipsoidal shape or the dumbbell shape, thereby each detecting element 511 can be uniform received the infrared light 411. (6) Because of the amplifier 721 on the second circuit board 72, noise of the signal transmission can be reduced effectively. (7) The power assembly 8 has the battery 81 and the power plug 82, whereby the gas sensor device can be carried, or the gas sensor device can be disposed on a fixed place.

The description above only illustrates specific embodiments and examples of the present invention. The instant disclosure should therefore cover various modifications and variations made to the herein-described structure and operations of the present invention, provided they fall within the scope of the instant disclosure as defined in the following appended claims.

What is claimed is:

1. A manufacturing method of a photoelectric gas sensor device, comprising the steps of:
(A) providing at least two half-housing modules from at least one corresponding mold;
(B) forming a reflecting layer on the ellipsoidal inner surface of each half-housing module;
(C) forming a chamber unit having a reflective ellipsoidal inner surface defining a chamber space from the half-housing modules;
(D) disposing an emitter assembly having an energy emitter at the first focal point of the ellipsoidal chamber; and
(E) disposing a receiver assembly having a detector unit at the second focal point of the ellipsoidal chamber.
whereby the light emitted from the emitter assembly is reflect-able to and receivable by the receiver assembly.

2. The manufacturing method as claimed in claim 1, wherein using the half-housing module to form the two half-housings is used of an injection molding process, and the reflecting layer is coating on each inner surface of the two half-housings.

3. The manufacturing method as claimed in claim 1, wherein using the half-housing module to form the two half-housings is used of a perfusion forming process, and the reflecting layer is polishing or gold plating on each inner surface of the two half-housings.

4. The manufacturing method as claimed in claim 1, wherein the housing has at least one convection passage formed thereof.

5. The manufacturing method as claimed in claim 1, wherein the housing has at least one diffusion passage formed thereof.

6. The manufacturing method as claimed in claim 1, wherein each of the two half-housings has at least one protruding joint and at least one recessing slot, and the two half-housings are connected to each other by engaging the protruding joint to the recessing slot.

7. The manufacturing method as claimed in claim 1, further comprising the steps of:
providing a fine-adjustment mechanism to the half-housing modules for enabling clearance-adjustment between the half-housing modules,
whereby an energy beam from the emitter assembly is reflected to the receiver assembly by the reflecting layer, and the energy beam is formed a focusing plane on the receiver assembly.

8. The manufacturing method as claimed in claim 7, wherein the focusing plane is an ellipsoidal shape or a dumbbell shape by adjusting the fine-adjustment mechanism.

9. The manufacturing method as claimed in claim 1, further comprising the steps of
providing a first circuit board electrically connected to the emitter assembly;
connecting the first circuit board to a first edge of the housing;
providing a second circuit board electrically connected to the receiver assembly, and the second circuit board has an amplifier formed thereof;
connecting the second circuit board to a second edge of the housing, the second edge opposing to the first edge, wherein the first edge and the second edge are perpendicular to a major axis of the ellipsoidal chamber; and
providing a third circuit board disposed under the housing, and two sides of the third circuit board connected to the first circuit board and the second circuit board.

10. The manufacturing method as claimed in claim 7, further providing a fine-adjustment mechanism disposed between the first circuit board and the first edge of the housing, and between the second circuit board and the second edge of the housing, thereby the two half-housings are spaced disposed by moving the fine-adjustment mechanism.

11. The manufacturing method as claimed in claim 7, further providing a display disposed above the housing, and the display electrically connected to the third circuit board.

12. A photoelectric gas sensor device, comprising:
(A) a chamber unit having an ellipsoidal inner surface defining an ellipsoidal inner chamber,
wherein the chamber unit includes at least one convection passage permitting gas communication to the inner chamber;
(B) a reflecting layer disposed on the inner surface;
(C) a fine-adjustment mechanism for providing clearance adjustment between the half-housing modules;
(D) an emitter assembly having an energy emitter on the first focal point of the ellipsoidal chamber; and
(E) a receiver assembly having a detector unit on the second focal point of the ellipsoidal chamber;
whereby an energy beam emitted from the emitter assembly is reflected to and received by the receiver assembly.

13. The gas sensor module as claimed in claim 12, wherein the chamber unit comprises two identical half-housing modules.

14. The gas sensor device as claimed in claim 12, wherein the focusing plane is an ellipsoidal shape or a dumbbell shape.

15. The gas sensor device as claimed in claim 12, further comprising a diffusion passage permitting gas communication to the chamber of the housing.

16. The gas sensor device as claimed in claim 12, further comprising a circuit board assembly disposed outside the chamber, the circuit board assembly electrically connecting to the emitter assembly and the receiver assembly.

17. The gas sensor device as claimed in claim 15, wherein the circuit board assembly has a first circuit board, a second circuit board, and a third circuit board electrically connected to the first circuit board and the second circuit board, the first circuit board and the second circuit board are respectively connected to two edges of the housing, and the third circuit board is disposed under the housing.

18. The gas sensor device as claimed in claim 16, wherein the first circuit board has an adjustment hole formed thereof, the first circuit board is fixed on the housing by the fine-adjustment mechanism through the adjustment hole, and the two half-housings are spaced disposed by moving the fine-adjustment mechanism in the adjustment hole.

19. The gas sensor device as claimed in claim 12, further comprising a display disposed above the housing, and the display electrically connected to the circuit board assembly.
